(19) United States
(12) Patent Application Publication
(10) Pub. No.: US 2025/0168972 A1
(43) Pub. Date: May 22, 2025

(54) ELECTRONIC COMPONENT MOUNTING SUBSTRATE

(71) Applicant: IBIDEN CO., LTD., Ogaki (JP)

(72) Inventors: Haruhiko MORITA, Ogaki (JP); Mio TAKEYAMA, Ogaki (JP)

(73) Assignee: IBIDEN CO., LTD., Ogaki (JP)

(21) Appl. No.: 18/949,189

(22) Filed: Nov. 15, 2024

(30) Foreign Application Priority Data
Nov. 17, 2023 (JP) 2023-195549

(51) Int. Cl. H05K 1/02; H01L 23/00; H01L 23/367; H01L 25/065; H05K 1/11; H05K 1/18

(52) U.S. Cl. CPC H05K 1/0271; H01L 23/367; H01L 25/0655; H05K 1/115; H05K 1/181; H01L 24/16; H01L 2224/16235; H05K 2201/0275; H05K 2201/096

(57) ABSTRACT

An electronic component mounting substrate includes an electronic component, a printed wiring board that mounts the electronic component thereon, and a cover that accommodates and seals the electronic component mounted on the printed wiring board. The cover has an upper portion and a support portion supporting the upper portion such that the upper portion has a thickness of 2 mm or more, and the printed wiring board includes an upper build-up part and a lower build-up part such that the upper build-up part mounts the electronic component thereon and includes an uppermost resin insulating layer not containing a reinforcing material and that the lower build-up part includes a lowermost resin insulating layer including a reinforcing material.

### CROSS-REFERENCE TO RELATED APPLICATIONS

The present application is based upon and claims the benefit of priority to Japanese Patent Application No. 2023-195549, filed Nov. 17, 2023, the entire contents of which are incorporated herein by reference.

### BACKGROUND OF THE INVENTION

### Field of the Invention

The present invention relates to an electronic component mounting substrate.

### Description of Background Art

Japanese Patent Application Laid-Open Publication No. 2000-323613 describes a multilayer substrate. The entire contents of this publication are incorporated herein by reference.

### SUMMARY OF THE INVENTION

According to one aspect of the present invention, an electronic component mounting substrate includes an electronic component, a printed wiring board that mounts the electronic component thereon, and a cover that accommodates and seals the electronic component mounted on the printed wiring board. The cover has an upper portion and a support portion supporting the upper portion such that the upper portion has a thickness of 2 mm or more, and the printed wiring board includes an upper build-up part and a lower build-up part such that the upper build-up part mounts the electronic component thereon and includes an uppermost resin insulating layer not containing a reinforcing material and that the lower build-up part includes a lowermost resin insulating layer including a reinforcing material.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating an electronic component mounting substrate according to an embodiment of the present invention; and

FIG. 2 is a graph showing a relationship between a thickness of an upper portion of a cover and a warpage amount.

### DETAILED DESCRIPTION OF THE EMBODIMENTS

Embodiments will now be described with reference to the accompanying drawings, wherein like reference numerals designate corresponding or identical elements throughout the various drawings.

### Embodiment

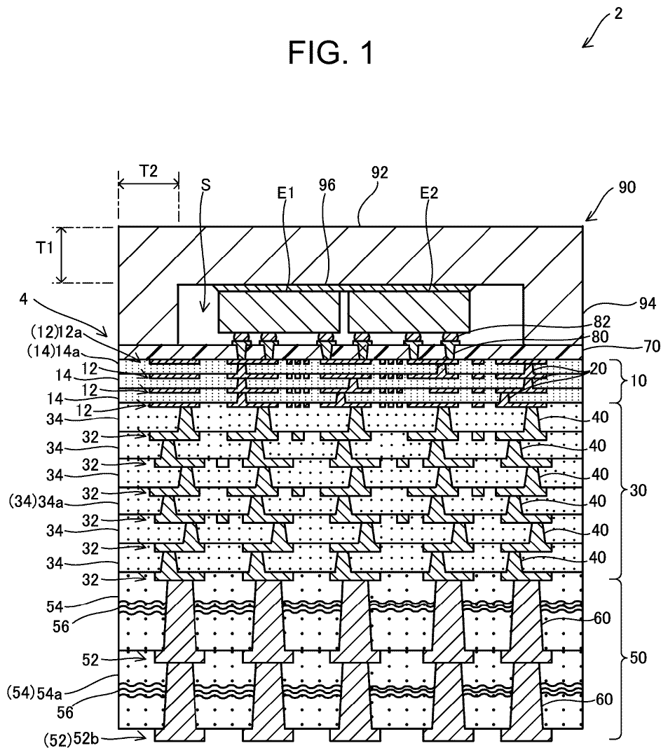

FIG. 1 is a cross-sectional view illustrating an electronic component mounting substrate 2 of an embodiment. As illustrated in FIG. 1, the electronic component mounting substrate 2 includes a printed wiring board 4 for mounting electronic components (E1, E2) and a cover 90 for sealing the electronic components (E1, E2). The printed wiring board 4 includes a third build-up part 50, a second build-up part 30, a first build-up part 10, a solder resist layer 70, mounting posts 80, and bumps 82. The printed wiring board 4 does not have a core substrate. The printed wiring board 4 is an asymmetric substrate. The second build-up part 30 is formed on the third build-up part 50. The first build-up part 10 is formed on the second build-up part 30. The solder resist layer 70 is formed on the first build-up part 10. The mounting posts 80 are formed in openings that penetrate the solder resist layer 70. The bumps 82 are formed on the mounting posts 80. The electronic components (E1, E2) are electrically connected to the printed wiring board 4 via the bumps 82.

The electronic components (E1, E2) are logic ICs. Examples of logic ICs include microprocessors, digital signal processors (DSPs), and the like.

The third build-up part 50 includes multiple third conductor layers 52 and multiple third resin insulating layers 54 that are alternately laminated, and third via conductors 60 that connect adjacent third conductor layers 52. The third conductor layers 52 are mainly formed of copper. The third conductor layers 52 include a lowermost conductor layer (52b). The third resin insulating layers 54 are formed using a thermosetting resin. An example of a thermosetting resin is an epoxy resin. The third resin insulating layers 54 each contain a reinforcing material 56 formed of a fiber. An example of a fiber is a glass cloth, or the like. The third resin insulating layers 54 may contain inorganic particles such as silica particles. The third resin insulating layers 54 include a lowermost resin insulating layer (54a). The third via conductors 60 are formed in openings that penetrate the third resin insulating layers 54. The third via conductors 60 are mainly formed of copper.

The second build-up part 30 includes multiple second conductor layers 32 and multiple second resin insulating layers 34 that are alternately laminated, and second via conductors 40 that connect adjacent second conductor layers 32. The second conductor layers 32 are mainly formed of copper. The second resin insulating layers 34 are formed using a thermosetting resin. An example of a thermosetting resin is an epoxy resin. The second resin insulating layers 34 contain inorganic particles such as silica particles. The second resin insulating layers 34 do not each contain a reinforcing material formed of a fiber. The second resin insulating layers 34 include a middle resin insulating layer (34a). The second via conductors 40 are formed in openings that penetrate the second resin insulating layers 34. The second via conductors 40 are mainly formed of copper.

The first build-up part 10 includes multiple first conductor layers 12 and multiple first resin insulating layers 14 that are alternately laminated, and first via conductors 20 that connect adjacent first conductor layers 12. The first conductor layers 12 are mainly formed of copper. The first conductor layers 12 include an uppermost conductor layer (12a). The uppermost conductor layer (12a) includes electrodes that are connected to the electronic components (E1, E2). The first resin insulating layers 14 are formed using a thermosetting resin. An example of a thermosetting resin is an epoxy resin. The first resin insulating layers 14 contain inorganic particles such as silica particles. The first resin insulating layers 14 do not each contain a reinforcing material formed of a fiber. The first resin insulating layers 14 include an uppermost resin insulating layer (14a). The first via conductors 20 are formed in openings that penetrate the first resin insulating layers 14. The first via conductors 20 are mainly formed of copper.

A thickness of each of the third resin insulating layers 54 is greater than a thickness of each of the second resin insulating layers 34. The thickness of each of the second resin insulating layers 34 is greater than a thickness of each of the first resin insulating layers 14. The thickness of the lowermost resin insulating layer (54a) is greater than the thickness of the uppermost resin insulating layer (14a). The thickness of each of the third resin insulating layers 54 is, for example, 90 μm or more and 110 μm or less. The thickness of each of the second resin insulating layers 34 is, for example, 20 μm or more and 25 μm or less. The thickness of each of the first resin insulating layers 14 is, for example, 8 μm or more and 12 μm or less. The thickness of each resin insulating layer corresponds to a distance between adjacent conductor layers.

A thickness of each of the third conductor layers 52 is greater than a thickness of each of the second conductor layers 32. The thickness of each of the second conductor layers 32 is greater than a thickness of each of the first conductor layers 12. The thickness of each of the third conductor layers 52 is, for example, 10 μm or more and 30 μm or less. The thickness of each of the second conductor layers 32 is, for example, 13 μm or more and 17 μm or less. The thickness of each of the first conductor layers 12 is, for example, 3 μm or more and 7 μm or less. A third conductor layer 52 for thickness measurement is sandwiched between third resin insulating layers 54. A second conductor layer 32 for thickness measurement is sandwiched between second resin insulating layers 34. A first conductor layer 12 for thickness measurement is sandwiched between first resin insulating layers 14.

The solder resist layer 70 is formed on the uppermost conductor layer (12a) and the uppermost resin insulating layer (14a). The solder resist layer 70 is formed using a photocurable resin. The mounting posts 80 are connected to the electrodes in the uppermost conductor layer (12a).

The mounting posts 80 are each formed by a via conductor filling an opening that penetrates the solder resist layer 70 and leads to one of the electrodes, and a protruding part. The protruding part protrudes from an upper surface of the solder resist layer 70. The protruding part is formed on the via conductor that fills the opening leading to one of the electrodes, and on the solder resist layer 70 around the opening leading to one of the electrode. The via conductor and the protruding part are integrally formed. The bumps 82 are formed on the mounting posts 80. The electronic components (E1, E2) are connected to the electrodes in the uppermost conductor layer (12a) via the bumps 82. The electronic components (E1, E2) are mounted on the first build-up part 10 via the bumps 82. The electronic components (E1, E2) are accommodated in a space(S) between the cover 90 and the printed wiring board 4.

The printed wiring board 4 has a thickness of 0.5 mm or more and 0.7 mm or less. A length of a short side of the printed wiring board 4 is 70 mm or more, and a length of a long side of the printed wiring board 4 is 250 mm or less.

The cover 90 seals the electronic components (E1, E2) mounted on the printed wiring board 4. The cover 90 is formed of an upper portion 92 and a support portion 94 that supports the upper portion 92. The support portion 94 has a substantially frame-like planar shape. An outer perimeter of the supporting portion 94 and an outer perimeter of the printed wiring board 4 are substantially identical. The upper portion 92 has a substantially rectangular planar shape. The planar shape of the upper portion 92 is substantially the same as a planar shape of the printed wiring board 4. The upper portion 92 substantially covers the upper surface of the printed wiring board 4. The support portion 94 and the upper portion 92 are integrally formed. The cover 90 can have openings penetrating the upper portion 92. The cover 90 can have openings penetrating the support portion 94. The number of the openings is preferably 2 or more. The openings can relieve a stress in the cover 90. The supporting portion 94 is adhered to the printed wiring board 4 with a resin adhesive (not illustrated). The space(S) is surrounded by the upper portion 92, the support portion 94, and the printed wiring board 4. The electronic components (E1, E2) and the upper portion 92 are adhered with a thermally conductive adhesive 96. When the electronic components (E1, E2) are adhered to the upper portion 92, heat generated by the electronic components (E1, E2) is dissipated through the cover 90. In another example, the electronic components (E1, E2) and the upper portion 92 are not adhered.

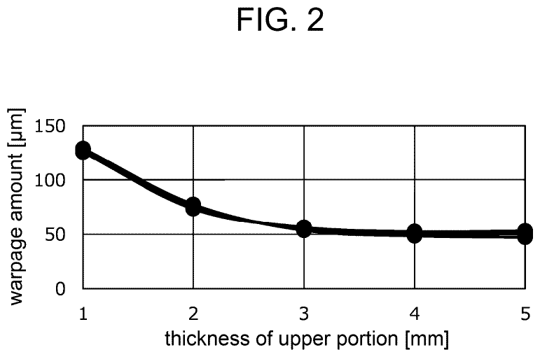

The upper portion 92 has a thickness (T1) of 2 mm or more. The thickness (T1) is preferably 3 mm or more and 10 mm or less. The thickness (T1) is more preferably 3 mm or more and 5 mm or less. The thickness (T1) of the upper portion 92 is 5 or more and 7 or less times the thickness of the printed wiring board 4. The support portion 94 has a thickness (T2) of, for example, 6 mm or more and 10 mm or less. FIG. 2 is a graph showing a relationship between the thickness (T1) of the upper portion 92 of the cover 90 and a warpage amount of the printed wiring board 4. As shown in FIG. 2, when the thickness (T1) of the upper portion 92 is 2 mm or more, the embodiment can suppress the warpage of the printed wiring board 4. When the thickness (T1) is 3 mm or more, the warpage amount of the printed wiring board 4 substantially does not change. When the thickness (T1) exceeds 5 mm, the weight of the cover 90 may affect the reliability of the electronic component mounting substrate. When the thickness (T1) exceeds 10 mm, for example, when the electronic component mounting substrate is dropped, wirings in the electronic component mounting substrate may be disconnected.

A material forming the cover 90 has a Young's modulus of 100 GPa or more. The Young's modulus of the material forming the cover 90 is preferably 150 GPa or more. The Young's modulus of the material forming the cover 90 is more preferably 190 GPa or more. The upper portion 92 has a Young's modulus of 100 GPa or more. The Young's modulus of the upper portion 92 is preferably 150 GPa or more. The Young's modulus of the upper portion 92 is more preferably 190 GPa or more. The Young's modulus is measured at 25 degrees Celsius. The cover 90 of the embodiment is formed of a metal. Examples of the metal include stainless steel and copper. When the cover 90 is formed of a metal, heat generated by the electronic components (E1, E2) is effectively dissipated through the cover 90.

### Method for Manufacturing Electronic Component Mounting Substrate

The first build-up part 10 is formed under a support plate. The second build-up part 30 is formed under the first build-up part 10. After that, the third build-up part 50 is formed under the second build-up part 30. The support plate is removed. The solder resist layer 70, the mounting posts 80, and the bumps 82 are formed on the exposed first build-up part 10. The printed wiring board 4 is formed. The printed wiring board 4 of the embodiment is formed by sequentially laminating the resin insulating layers from the uppermost resin insulating layer (14a) to the lowermost resin insulating layer (54a). The printed wiring board 4 of the embodiment includes the third build-up part 50 and the first build-up part 10, which is formed on the third build-up part 50. The third build-up part 50 includes the lowermost resin insulating layer (54a), and the first build-up part 10 includes the uppermost resin insulating layer (14a). The printed wiring board 4 of the embodiment includes the first build-up part 10 on the second build-up part 30, and the third build-up part 50 under the second build-up part 30. The third resin insulating layers 54 forming the third build-up part 50 each contain the reinforcement material 56 formed of a fiber, while the first resin insulating layers 14 forming the first build-up part 10 do not each contain the reinforcement material 56 formed of a fiber. The second build-up part 30 includes the middle resin insulating layer (34a). The second resin insulating layers 34 forming the second build-up part 30 do not each contain the reinforcement material 56 formed of a fiber. In this way, the printed wiring board 4 of the embodiment is an asymmetric substrate. The printed wiring board 4 of the embodiment tends to have significant warpage.

The electronic components (E1, E2) are mounted on the first build-up part 10 via the bumps 82. The electronic components (E1, E2) are sealed by the cover 90. The electronic components (E1, E2) are accommodated in the space(S) between the cover 90 and the printed wiring board 4. The electronic component mounting substrate 2 is obtained.

The third resin insulating layers 54 each contain the reinforcing material 56 formed of a fiber. The first resin insulating layers 14 and the second resin insulating layers 34 do not each contain the reinforcement material 56 formed of a fiber. Therefore, strength of each of the third resin insulating layers 54 is higher than strength of each of the first resin insulating layers 14 and the second resin insulating layers 34. Strength of the third build-up part 50 is higher than strength of each of the second build-up part 30 and the first build-up part 10. In the electronic component mounting substrate 2 of the embodiment, the low-strength first build-up part 10 and the low-strength second build-up part 30 are sandwiched between the high-strength upper portion 92 and the high-strength third build-up part 50. In the electronic component mounting substrate 2 of the embodiment, the high-strength portions sandwich the low-strength portions. The high-strength portions are formed on the two sides. Warpage of the electronic component mounting substrate 2 is reduced. The electronic component mounting substrate 2 can suppress the warpage of the printed wiring board 4.

Japanese Patent Application Laid-Open Publication No. 2000-323613 describes a multilayer substrate having a frame that acts as a reinforcing member.

It is thought that when the multilayer substrate of Japanese Patent Application Laid-Open Publication No. 2000-323613 is large in size, it is difficult to suppress warping in the multilayer substrate.

An electronic component mounting substrate according to an embodiment of the present invention includes a printed wiring board that includes a third build-up part that includes a lowermost resin insulating layer that contains a reinforcing material; and a first build-up part that is formed on the third build-up part and includes an uppermost resin insulating layer that does not contain a reinforcing material; and a cover for sealing an electronic component positioned on the first build-up part. The electronic component is mounted on the first build-up part, the electronic component is accommodated in a space between the cover and the printed wiring board, the cover is formed of an upper portion and a support portion that supports the upper portion, and the upper portion has a thickness of 2 mm or more.

An electronic component mounting substrate according to an embodiment of the present invention is formed of a printed wiring board and a cover, and the cover has a thickness of 2 mm or more. The cover having the thick upper member acts as a reinforcing member. Therefore, even when the printed wiring board is a wiring substrate (asymmetric substrate) formed of the third build-up part and the first build-up part, the printed wiring board is unlikely to warp. Warpage of the electronic component mounting substrate is reduced.

Obviously, numerous modifications and variations of the present invention are possible in light of the above teachings. It is therefore to be understood that within the scope of the appended claims, the invention may be practiced otherwise than as specifically described herein.

1. An electronic component mounting substrate, comprising:
an electronic component;
a printed wiring board configured to mount the electronic component thereon; and
a cover configured to accommodate and seal the electronic component mounted on the printed wiring board,
wherein the cover has an upper portion and a support portion supporting the upper portion such that the upper portion has a thickness of 2 mm or more, and the printed wiring board includes an upper build-up part and a lower build-up part such that the upper build-up part is configured to mount the electronic component thereon and includes an uppermost resin insulating layer not containing a reinforcing material and that the lower build-up part includes a lowermost resin insulating layer comprising a reinforcing material.

2. The electronic component mounting substrate according to claim 1, wherein the cover is formed such that the thickness of the upper portion is in a range of 3 mm to 10 mm.

3. The electronic component mounting substrate according to claim 1, wherein the cover is formed such that the thickness of the upper portion is in a range of 3 mm to 5 mm.

4. The electronic component mounting substrate according to claim 1, wherein the upper build-up part includes a plurality of conductor layers and a plurality of resin insulating layers including the uppermost resin insulating layer and each not containing a reinforcing material, and the lower build-up part includes a plurality of conductor layers and a plurality of resin insulating layers including the lowermost resin insulating layer and each comprising a reinforcing material.

5. The electronic component mounting substrate according to claim 1, further comprising:
a middle build-up part formed between the upper build-up part and the lower build-up part and comprising a middle resin insulating layer such that the middle resin insulating layer does not contain a reinforcing material.

6. The electronic component mounting substrate according to claim 5, wherein the upper build-up part includes a plurality of conductor layers and a plurality of resin insulating layers including the uppermost resin insulating layer and each not containing a reinforcing material, the middle build-up part includes a plurality of conductor layers and a plurality of resin insulating layers including the middle resin insulating layer and each not containing a reinforcing material, and the lower build-up part includes a plurality of conductor layers and a plurality of resin insulating layers including the lowermost resin insulating layer and each comprising a reinforcing material including a fiber.

7. The electronic component mounting substrate according to claim 6, wherein the upper, middle and lower build-up parts are formed such that each of the resin insulating layers in the lower build-up part has a thickness that is greater than a thickness of each of the resin insulating layers in the middle build-up part, the thickness of each of the resin insulating layers in the middle build-up part is greater than a thickness of each of the resin insulating layers in the upper build-up part, each of the conductor layers in the lower build-up part has a thickness that is greater than a thickness of each of the conductor layers in the middle build-up part, and the thickness of each of the conductor layers in the middle build-up part is greater than a thickness of each of the conductor layers in the upper build-up part.

8. The electronic component mounting substrate according to claim 1, wherein the upper and lower build-up parts are formed such that the lowermost resin insulating layer has a thickness that is greater than a thickness of the uppermost resin insulating layer.

9. The electronic component mounting substrate according to claim 1, wherein the cover is formed such that the thickness of the upper portion is in a range of 5 to 7 times a thickness of the printed wiring board.

10. The electronic component mounting substrate according to claim 1, wherein the printed wiring board has a thickness in a range of 0.5 mm to 0.7 mm.

11. The electronic component mounting substrate according to claim 1, wherein the printed wiring board is formed such that a length of a short side of the printed wiring board is 70 mm or more and a length of a long side of the printed wiring board is 250 mm or less.

12. The electronic component mounting substrate according to claim 1, wherein the cover comprises a material having a Young's modulus of 100 GPa or more at 25° C.

13. The electronic component mounting substrate according to claim 12, wherein the Young's modulus of the material forming the cover is 150 GPa or more.

14. The electronic component mounting substrate according to claim 12, wherein the Young's modulus of the material forming the cover is 190 GPa or more.

15. The electronic component mounting substrate according to claim 1, wherein the cover is formed of a metal.

16. The electronic component mounting substrate according to claim 1, wherein the cover comprises a metal.

17. The electronic component mounting substrate according to claim 2, wherein the upper build-up part includes a plurality of conductor layers and a plurality of resin insulating layers including the uppermost resin insulating layer and each not containing a reinforcing material, and the lower build-up part includes a plurality of conductor layers and a plurality of resin insulating layers including the lowermost resin insulating layer and each comprising a reinforcing material.

18. The electronic component mounting substrate according to claim 2, further comprising:
a middle build-up part formed between the upper build-up part and the lower build-up part and comprising a middle resin insulating layer such that the middle resin insulating layer does not contain a reinforcing material.

19. The electronic component mounting substrate according to claim 18, wherein the upper build-up part includes a plurality of conductor layers and a plurality of resin insulating layers including the uppermost resin insulating layer and each not containing a reinforcing material, the middle build-up part includes a plurality of conductor layers and a plurality of resin insulating layers including the middle resin insulating layer and each not containing a reinforcing material, and the lower build-up part includes a plurality of conductor layers and a plurality of resin insulating layers including the lowermost resin insulating layer and each comprising a reinforcing material including a fiber.

20. The electronic component mounting substrate according to claim 19, wherein the upper, middle and lower build-up parts are formed such that each of the resin insulating layers in the lower build-up part has a thickness that is greater than a thickness of each of the resin insulating layers in the middle build-up part, the thickness of each of the resin insulating layers in the middle build-up part is greater than a thickness of each of the resin insulating layers in the upper build-up part, each of the conductor layers in the lower build-up part has a thickness that is greater than a thickness of each of the conductor layers in the middle build-up part, and the thickness of each of the conductor layers in the middle build-up part is greater than a thickness of each of the conductor layers in the upper build-up part.
